(19) United States
(12) Patent Application Publication
(10) Pub. No.: US 2026/0006901 A1
(43) Pub. Date: Jan. 1, 2026

(54) SHIFTED STACKED FETS WITH BACKSIDE S/D CONTACTS

(71) Applicant: INTERNATIONAL BUSINESS MACHINES CORPORATION, Armonk, NY (US)

(72) Inventors: Sarah Nahar Chowdhury, Guilderland, NY (US); Ruilong Xie, Niskayuna, NY (US); Chen Zhang, Santa Clara, CA (US); Shay Reboh, Guilderland, NY (US)

(21) Appl. No.: 18/760,425

(22) Filed: Jul. 1, 2024

(51) Int. Cl. H01L 27/088; H01L 23/528; H01L 23/532; H01L 29/06; H01L 29/40; H01L 29/417; H01L 29/423; H01L 29/66; H01L 29/775; H01L 29/786

(52) U.S. Cl. CPC H10D 84/83; H01L 23/5286; H01L 23/5329; H10D 64/254; H10D 30/014; H10D 30/43; H10D 30/6735; H10D 30/6757; H10D 62/121; H10D 64/01

(57) ABSTRACT

Semiconductor devices include a first bottom field effect transistor (FET) having a bottom source/drain (S/D) structure. A top FET is above the bottom FET and has a top S/D structure. A backside top contact is in electrical contact with a bottom surface and a side surface of the top S/D structure and extends below the bottom FET. A dielectric liner, disposed along sidewalls of the backside top contact, separates the backside top contact from the bottom S/D structure.

### BACKGROUND

The present invention generally relates to semiconductor device fabrication and, more particularly, to stacked field effect transistors (FETs).

The density of integrated circuits can be increased by stacking devices vertically with respect to one another. This can be particularly advantageous when forming complementary devices, where a top FET may have a first polarity and a bottom FET may have a second polarity.

However, connecting such devices to one another can be challenging, as fabrication processes may have difficulty reaching the bottom FET from the top of the device, or the top FET from the bottom of the device. While shifting the stacked devices laterally with respect to one another can help by providing an exposed contact surface for source/drain (S/D) structure, the small size of the contact area may create challenges for mask placement and contact resistance.

### SUMMARY

A semiconductor device includes a bottom field effect transistor (FET) having a bottom source/drain (S/D) structure. A top FET is above the bottom FET and has a top S/D structure. A backside top contact is in electrical contact with a bottom surface and a side surface of the top S/D structure and extends below the bottom FET. A dielectric liner, disposed along sidewalls of the backside top contact, separates the backside top contact from the bottom S/D structure.

A semiconductor device includes a first bottom FET having a first bottom S/D structure. A first top FET is above the first bottom FET and has a first top S/D structure that is laterally shifted relative to the first bottom S/D structure. A backside power plane is below the first bottom FET. A backside bottom contact makes an electrical connection between the backside power plane and the first bottom S/D structure. A backside top contact extends through the backside power plane from below the first bottom FET and is in electrical contact with a bottom surface and side surface of the first top S/D structure. A dielectric liner, disposed along sidewalls of the backside top contact, separates the backside top contact from the backside power plane.

A semiconductor device includes a first bottom FET having a first bottom S/D structure. A first top FET is above the first bottom FET, having a first top S/D structure. A second top FET is adjacent to the first top FET. A second bottom FET is adjacent to the first bottom FET. A backside top contact is in electrical contact with a bottom surface and side surface of the first top S/D structure that extends below the first bottom FET. A dielectric liner, disposed along sidewalls of the backside top contact, separates the backside top contact from the first bottom S/D structure. A gate cut structure isolates the backside top contact from the second top FET and includes a dielectric liner of a first dielectric material and a dielectric fill of a second dielectric material.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a set of stacked, shifted field effect transistors (FETs) that illustrates a set of cross-sectional planes, in accordance with an embodiment of the present invention;

FIG. 2 is a set of cross-sectional views of a step in the fabrication of a semiconductor device that includes a backside contact to a top FET that makes contact with a bottom and side surface of a top source/drain (S/D) structure, illustrating formation of placeholder structures through a bottom layer, in accordance with an embodiment of the present invention;

FIG. 3 is a set of cross-sectional views of a step in the fabrication of the semiconductor device that includes the backside contact to a top FET that makes contact with a bottom and side surface of a top S/D structure, illustrating the formation of alternating semiconductor layers over the bottom layer, in accordance with an embodiment of the present invention;

FIG. 4 is a set of cross-sectional views of a step in the fabrication of a semiconductor device that includes a backside contact to a top FET that makes contact with a bottom and side surface of a top S/D structure, the formation of dummy gates and channels above the bottom layer, in accordance with an embodiment of the present invention;

FIG. 5 is a set of cross-sectional views of a step in the fabrication of a semiconductor device that includes a backside contact to a top FET that makes contact with a bottom and side surface of a top S/D structure, illustrating the formation of an interlayer placeholder in a bonding layer, in accordance with an embodiment of the present invention;

FIG. 6 is a set of cross-sectional views of a step in the fabrication of a semiconductor device that includes a backside contact to a top FET that makes contact with a bottom and side surface of a top S/D structure, illustrating the formation of top S/D structures, in accordance with an embodiment of the present invention;

FIG. 7 is a set of cross-sectional views of a step in the fabrication of a semiconductor device that includes a backside contact to a top FET that makes contact with a bottom and side surface of a top S/D structure, illustrating the formation of a top interlayer dielectric and a top placeholder structure, in accordance with an embodiment of the present invention;

FIG. 8 is a set of cross-sectional views of a step in the fabrication of a semiconductor device that includes a backside contact to a top FET that makes contact with a bottom and side surface of a top S/D structure, illustrating the replacement of sacrificial semiconductor layers with a gate stack, in accordance with an embodiment of the present invention;

FIG. 9 is a set of cross-sectional views of a step in the fabrication of a semiconductor device that includes a backside contact to a top FET that makes contact with a bottom and side surface of a top S/D structure, illustrating the formation of a top gate cut and a frontside contact to a bottom S/D structure, in accordance with an embodiment of the present invention;

FIG. 10 is a set of cross-sectional views of a step in the fabrication of a semiconductor device that includes a backside contact to a top FET that makes contact with a bottom and side surface of a top S/D structure, illustrating the removal of the substrate and the formation of a backside interlayer dielectric, in accordance with an embodiment of the present invention;

FIG. 11 is a set of cross-sectional views of a step in the fabrication of a semiconductor device that includes a backside contact to a top FET that makes contact with a bottom and side surface of a top S/D structure, illustrating the replacement of a bottom placeholder structure with a conductive contact, in accordance with an embodiment of the present invention;

FIG. 12 is a set of cross-sectional views of a step in the fabrication of a semiconductor device that includes a backside contact to a top FET that makes contact with a bottom and side surface of a top S/D structure, illustrating the formation of a via to a backside placeholder structure, in accordance with an embodiment of the present invention;

FIG. 13 is a set of cross-sectional views of a step in the fabrication of a semiconductor device that includes a backside contact to a top FET that makes contact with a bottom and side surface of a top S/D structure, illustrating the removal of placeholder structures to expose surfaces of a top S/D structure, in accordance with an embodiment of the present invention;

FIG. 14 is a set of cross-sectional views of a step in the fabrication of a semiconductor device that includes a backside contact to a top FET that makes contact with a bottom and side surface of a top S/D structure, illustrating the formation of a backside contact to the top S/D structure, in accordance with an embodiment of the present invention; and

FIG. 15 is a block/flow diagram of a method for fabricating a semiconductor device that includes a backside contact to a top FET that makes contact with a bottom and side surface of a top S/D structure, in accordance with an embodiment of the present invention.

### DETAILED DESCRIPTION

Shifted, stacked field effect transistors (FETs) may include a backside contact to a source/drain (S/D) structure of the top FET. The backside contact may be formed along a bottom and side surface of the S/D structure and may have a dielectric lining in the area where it passes through the bottom FET to prevent shorting to conductive structures of the bottom FET.

According to an aspect of the invention, there is provided a semiconductor device that includes a bottom field effect transistor (FET) having a bottom source/drain (S/D) structure. A top FET is above the bottom FET and has a top S/D structure. A backside top contact is in electrical contact with a bottom surface and a side surface of the top S/D structure and extends below the bottom FET. A dielectric liner, disposed along sidewalls of the backside top contact, separates the backside top contact from the bottom S/D structure. The backside top contact making the electrical connection along the bottom surface and side surface of the top S/D structure reduces contact resistance.

In embodiments, the top S/D structure is laterally shifted relative to the bottom S/D structure. This lateral shift makes it possible to reach the top S/D structure from below without complicated backside contact shapes.

In embodiments, a backside power plane is below the bottom FET. This provides power to devices from the back side of the device, which increases the options for layout of the device.

In embodiments, the backside top contact penetrates the backside power plane, with the dielectric liner insulating the backside top contact from the backside power plane. Using the dielectric liner, the backside top contact can be formed without regard for shorting to adjacent structures, thereby increasing the options for layout of the device.

In embodiments, a backside bottom contact is in electrical contact with the backside power plane and the bottom S/D structure. The backside bottom contact thereby makes it possible to provide connections to bottom S/D structures and increases the options for layout of the device.

In embodiments, the dielectric liner is in direct contact with the backside bottom contact. Using the dielectric liner, the backside top contact can be formed without regard for shorting to adjacent structures, thereby increasing the options for layout of the device.

In embodiments, a gate cut structure isolates the backside top contact from a neighboring top FET. The gate cut structure can be formed using the same process steps as formation of frontside bottom contacts through a top layer of the device.

In embodiments, the gate cut structure includes a dielectric liner of a first dielectric material and a dielectric fill of a second dielectric material. The dielectric liner of the gate cut structure can be formed along with a similar liner in frontside bottom contacts, and the remainder of the gate cut can be filled with the dielectric fill, so that the gate cut structure can be integrated with the process for forming contacts.

In embodiments, the first dielectric material is silicon nitride and the second dielectric material is silicon dioxide. These materials are selectively etchable with respect to one another.

In embodiments, the side surface of the top S/D structure is a flat, vertical surface. The flat surface of the top S/D structure makes a reliable and low-resistance electrical connection with the backside top contact.

According to an aspect of the invention, there is provided a semiconductor device that includes a first bottom FET having a first bottom S/D structure. A first top FET is above the first bottom FET and has a first top S/D structure that is laterally shifted relative to the first bottom S/D structure. A backside power plane is below the first bottom FET. A backside bottom contact that is in electrical contact with the backside power plane and the first bottom S/D structure. A backside top contact extends through the backside power plane from below the first bottom FET and is in electrical contact with a bottom surface and side surface of the first top S/D structure. A dielectric liner, disposed along sidewalls of the backside top contact, separates the backside top contact from the backside power plane. The backside top contact making the electrical connection along the bottom surface and side surface of the first top S/D structure reduces contact resistance. Using the dielectric liner, the backside top contact can be formed without regard for shorting to adjacent structures, thereby increasing the options for layout of the device.

In embodiments, a second top FET is adjacent to the first top FET, with a gate cut structure isolating the backside top contact from a second top S/D structure of the second top FET. The gate cut structure can be formed using the same process steps as formation of frontside bottom contacts through a top layer of the device.

In embodiments, the gate cut structure includes a dielectric liner of a first dielectric material and a dielectric fill of a second dielectric material. The dielectric liner of the gate cut structure can be formed along with a similar liner in frontside bottom contacts, and the remainder of the gate cut can be filled with the dielectric fill, so that the gate cut structure can be integrated with the process for forming contacts.

In embodiments, a second bottom FET is adjacent to the first bottom FET, with a second bottom S/D structure that is laterally shifted relative to the second top S/D structure. This lateral shift makes it possible to reach the top S/D structure from below without complicated backside contact shapes.

In embodiments, a frontside top contact makes an electrical connection to the second top S/D structure from above the first top FET and a frontside bottom contact that makes an electrical connection to the second bottom S/D structure from above the first top FET. The use of both frontside and backside contacts on different FETs increases the options for layout of the device.

According to an aspect of the invention, a semiconductor device includes a first bottom FET having a first bottom S/D structure. A first top FET is above the first bottom FET, having a first top S/D structure. A second top FET is adjacent to the first top FET. A second bottom FET is adjacent to the first bottom FET. A backside top contact is in electrical contact with a bottom surface and side surface of the first top S/D structure that extends below the first bottom FET. A dielectric liner, disposed along sidewalls of the backside top contact, separates the backside top contact from the first bottom S/D structure. A gate cut structure isolates the backside top contact from the second top FET and includes a dielectric liner of a first dielectric material and a dielectric fill of a second dielectric material.

The backside top contact making the electrical connection along the bottom surface and side surface of the first top S/D structure reduces contact resistance. The dielectric liner of the gate cut structure can be formed along with a similar liner in frontside bottom contacts, and the remainder of the gate cut can be filled with the dielectric fill, so that the gate cut structure can be integrated with the process for forming contacts.

In embodiments, a backside power plane is below the first bottom FET. This provides power to devices from the back side of the device, which increases the options for layout of the device.

In embodiments, the backside top contact penetrates the backside power plane, with the dielectric liner insulating the backside top contact from the backside power plane. Using the dielectric liner, the backside top contact can be formed without regard for shorting to adjacent structures, thereby increasing the options for layout of the device.

In embodiments, a backside bottom contact that is in electrical contact with the backside power plane and the first bottom S/D structure. The backside bottom contact thereby makes it possible to provide connections to bottom S/D structures and increases the options for layout of the device.

In embodiments, the dielectric liner is in direct contact with the backside bottom contact. Using the dielectric liner, the backside top contact can be formed without regard for shorting to adjacent structures, thereby increasing the options for layout of the device.

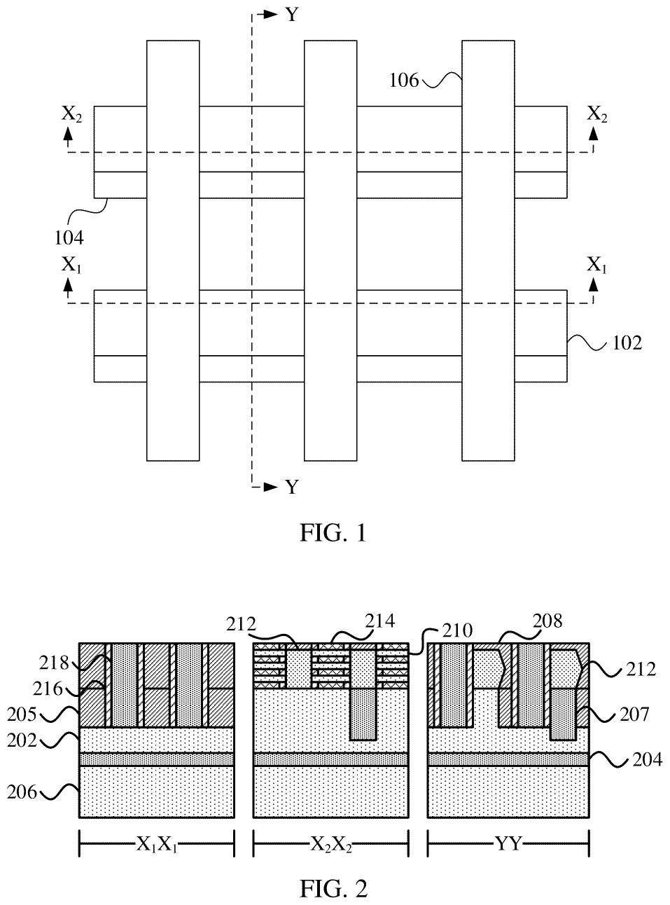

Referring now to FIG. 1, a top-down view of a semiconductor device is shown, including shifted stacked FETs. The top-down view shows top FET channels 102 and bottom FET channels 104, being laterally shifted with respect to one another such that there is a region of overlap and a region where each bottom FET channel 104 is partially exposed next to the respective top FET channel 102.

The top-down view indicates a set of cross-sectional planes that will be shown with greater detail in the following drawings. These include a cross-section X₁X₁ that cuts parallel along both a top FET channel 102 and a bottom FET channel 104 in a region of overlap, a cross-section X₂X₂ that cuts parallel along a top FET channel 102 in a region where the two FET channels do not overlap, and a cross-section YY that cuts perpendicular to the FET channels in a region between adjacent gates 106.

It should be understood that the arrangement of the top FET channels, the bottom FET channels 104, and the gates 106 is provided solely for the sake of illustration and should not be seen as limiting. The following figures are not necessarily at the same scale as the elements shown in FIG. 1, nor should they be seen as being limiting in terms of size, proportion, or relative positioning of the depicted elements.

Referring now to FIG. 2, a set of cross-sectional views is shown of a step in the fabrication of shifted stacked FETs. A bottom FET layer is formed on a semiconductor substrate 202. The semiconductor substrate is itself formed on a carrier substrate 206, with an etch stop layer 204 between them.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The etch stop layer 204 may be, for example, a semiconductor material having etch selectivity with respect to the semiconductor substrate 202, for example silicon germanium alloys of different molar ratios when silicon is used in the semiconductor substrate 202 and the carrier substrate 206.

Shallow trench isolation (STI) structures 205 are formed in the semiconductor substrate 202, for example by etching trenches into the semiconductor substrate 202 and filling the trenches with dielectric material, such as silicon dioxide. Backside bottom contact placeholder 207 is similarly formed in the semiconductor substrate 202, but may be formed from a selectively etchable material such as silicon germanium alloy.

A set of bottom channel layers 210 are formed over the semiconductor substrate 202, for example by epitaxially growing a set of alternating layers of channel material and sacrificial material. The channel material may be silicon, for example, and the sacrificial material may be a material that is crystallographically compatible with silicon, such as silicon germanium. Bottom S/D structures 212 can be epitaxially grown from side surfaces of the bottom channel layers 210. Because silicon germanium can be selectively etched with respect to silicon, the sacrificial layers can be etched away after the formation of inner spacers to leave the bottom channel layers 210 suspended from the bottom S/D structures 212. A bottom gate stack 214 can then be formed on and around the bottom channel layers 210. A bottom interlayer dielectric 208 is formed around the bottom channel layers 210 and bottom S/D structures 212, for example using silicon dioxide and/or silicon nitride.

The bottom gate stack 214 may include a gate dielectric, an optional work function metal, and a gate conductor. The gate dielectric may include a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum. The gate conductor may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon. The optional work function metal layer may include any appropriate work function metal to achieve a p-type threshold voltage shift or n-type threshold voltage shift, as appropriate. The work function metal layer can be formed of multiple sublayers to control the p-type and n-type threshold voltage.

Backside bottom contact placeholder 218 may be formed in vias through the bottom layer, with dielectric contact spacers 216. The dielectric contact spacers 216 may contact the bottom S/D structures 212, insulating the bottom layer placeholder 218 from the bottom S/D structures 212. The dielectric contact spacers 216 may be formed from any appropriate dielectric material, such as silicon nitride, and the backside contact placeholders may be formed by, e.g., silicon germanium.

The terms “epitaxial growth” and/or “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

Other types of material deposition that may be used herein include chemical vapor deposition (CVD), physical vapor deposition (PVD), atomic layer deposition (ALD), or gas cluster ion beam (GCIB) deposition. Some deposition processes, such as ALD, may deposit material conformally, whereas others, such as PVD or GCIB, may provide a more directional deposition. CVD may range from highly conformal to highly non-conformal depending on the formulation. The substrate holders for deposition can be static or rotating.

As used herein, the term “selective” in reference to a material removal process denotes that the rate of material removal for a first material is greater than the rate of removal for at least another material of the structure to which the material removal process is being applied.

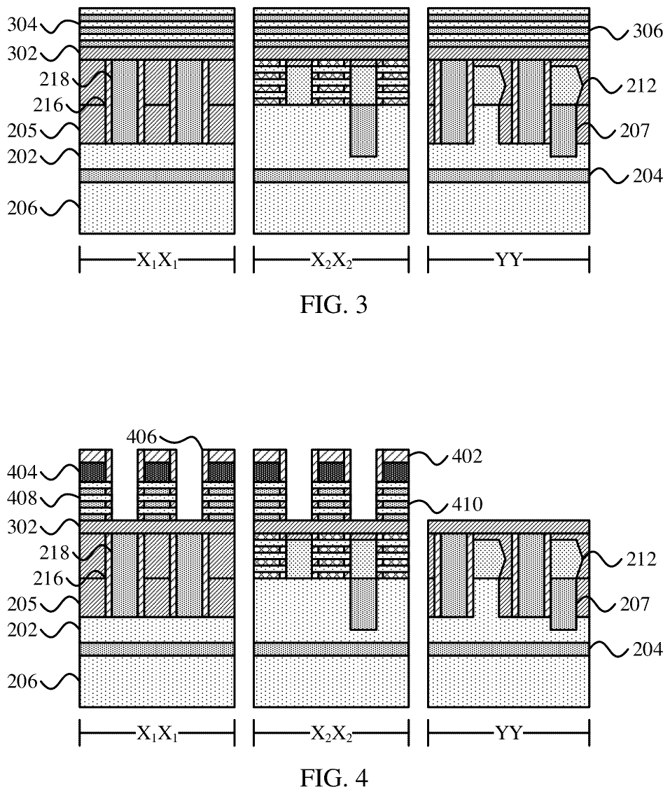

Referring now to FIG. 3, a set of cross-sectional views is shown of a step in the fabrication of shifted stacked FETs. A wafer of alternating semiconductors is bonded to the top surface of the bottom interlayer dielectric 208 using a layer of bonding oxide 302. The alternating semiconductors include upper channel layers 304 and sacrificial layers 306, which may be formed by alternating epitaxial growth processes using, e.g., silicon and silicon germanium respectively. Once the wafer of alternating semiconductors has been formed, it can be maneuvered onto the bottom layer with a carrier wafer for bonding and the carrier wafer can then be removed from the bonded surface.

Referring now to FIG. 4, a set of cross-sectional views is shown of a step in the fabrication of shifted stacked FETs. Dummy gates 404 are formed over the alternating semiconductor layers using a photolithographic etch process to form masks 402, followed by a selective anisotropic etch of a layer of dummy gate material (e.g., polysilicon) to define the dummy gates 404. Dielectric sidewall spacers 406 are formed on the sides of the dummy gates 404 by a conformal deposition of dielectric material, such as silicon nitride, followed by a selective anisotropic etch to remove the dielectric material from horizontal surfaces.

After formation of the dummy gates 404 and the dielectric sidewall spacers 406, one or more selective anisotropic etches are performed to remove exposed portions of the upper channel layers 304 and sacrificial layers 306, forming upper channels 408. The remaining sacrificial material may be selectively and isotropically etched to create recessed sacrificial layers 410, and inner spacers may be formed in the recesses with a conformal deposition of dielectric material, such as silicon dioxide, or by high temperature silicon nitride followed by a wet etch strip and clean that removes any of the dielectric material that is not protected by the recesses.

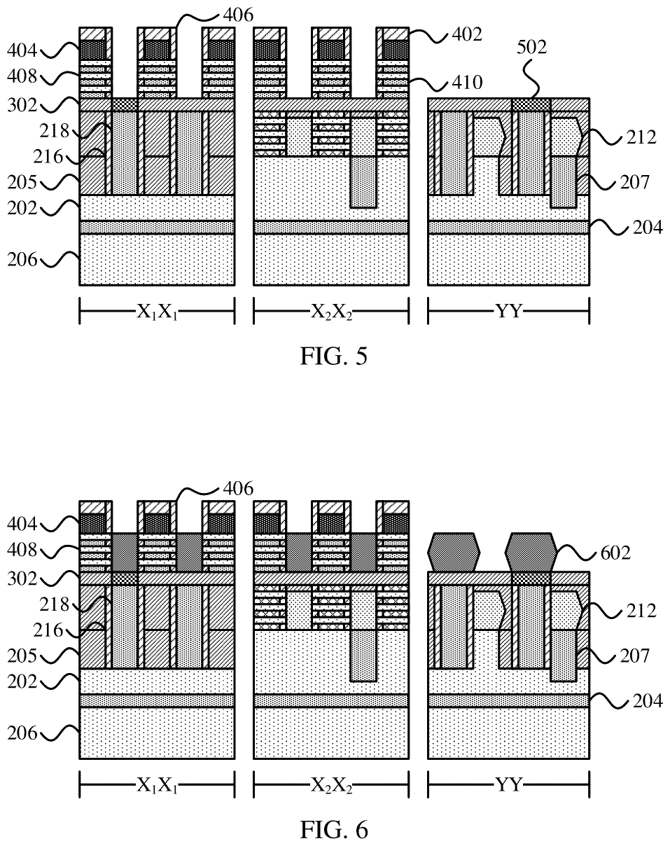

Referring now to FIG. 5, a set of cross-sectional views is shown of a step in the fabrication of shifted stacked FETs. An interlayer placeholder 502 is formed in the layer of bonding oxide or adhesives 302, for example by lithographically patterning and anisotropically etching a trench into the bonding oxide and depositing an appropriate sacrificial material. The bonding oxide can be of different porosities and variable bonding energy of silicon oxide, and silane-based low-temperature oxide. The interlayer placeholder 502 is formed in a region directly above one of the bottom layer placeholder 218 where all the placeholders are made of sacrificial materials. The contact between the placeholders makes it possible to remove them in subsequent processing steps to create a continuous cavity for the formation of a contact.

Referring now to FIG. 6, a set of cross-sectional views is shown of a step in the fabrication of shifted stacked FETs. Top S/D structures 602 are epitaxially grown form exposed side surfaces of the upper channels 408. In some embodiments the top S/D structures 602 may be formed from a different semiconductor material and may have a different dopant polarity as compared to the bottom S/D structures 212. For example, the bottom S/D structures 212 may be formed with an n-type dopant and the top S/D structures 602 may be formed with a p-type dopant, or vice versa. In some embodiments the top S/D structures 602 may be formed with the same semiconductor material and/or dopant polarity as the bottom S/D structures 212. One of the top S/D structures 602 may make contact with the interlayer placeholder 502.

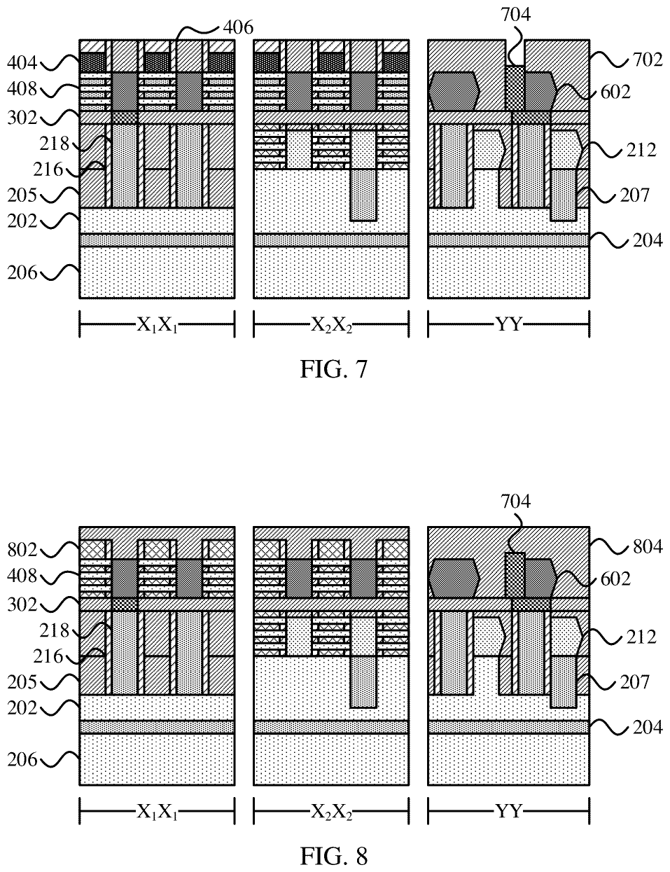

Referring now to FIG. 7, a set of cross-sectional views is shown of a step in the fabrication of shifted stacked FETs. A top interlayer dielectric 702 is formed, for example by any appropriate deposition of a dielectric material, such as a flowable CVD of silicon dioxide. An opening is formed through the top interlayer dielectric 702 in a region above the interlayer placeholder 502, which may further penetrate a corresponding top S/D structure 602 to expose a sidewall of the top S/D structure 602. A top layer placeholder 704 may be formed in the opening, in contact with the interlayer placeholder 502 and the exposed top S/D structure 602.

Referring now to FIG. 8, a set of cross-sectional views is shown of a step in the fabrication of shifted stacked FETs. The top interlayer dielectric 702 and the masks 402 are polished back using a chemical mechanical planarization (CMP) process to expose the dummy gates 404. The dummy gates 404 are selectively etched away, followed by recessed sacrificial layers 410, leaving the upper channels 408 suspended by the top S/D structures 602. CMP is performed using, e.g., a chemical or granular slurry and mechanical force to gradually remove upper layers of the device. The slurry may be formulated to be unable to dissolve, for example, the material of the dummy gates 404, resulting in the CMP process's inability to proceed any farther than that layer.

A top gate stack 802 is formed on and around the upper channels 408, including a gate dielectric layer, an optional work function metal layer, and a gate conductor. The top gate stack 802 may be formed from the same materials as the bottom gate stack 214 or may have different materials. For example, the optional work function metal of the top gate stack 802 may differ from that of the bottom gate stack 214, for example having different respective polarities (e.g., n-type or p-type). Additional dielectric material may then be deposited to form top interlayer dielectric 804.

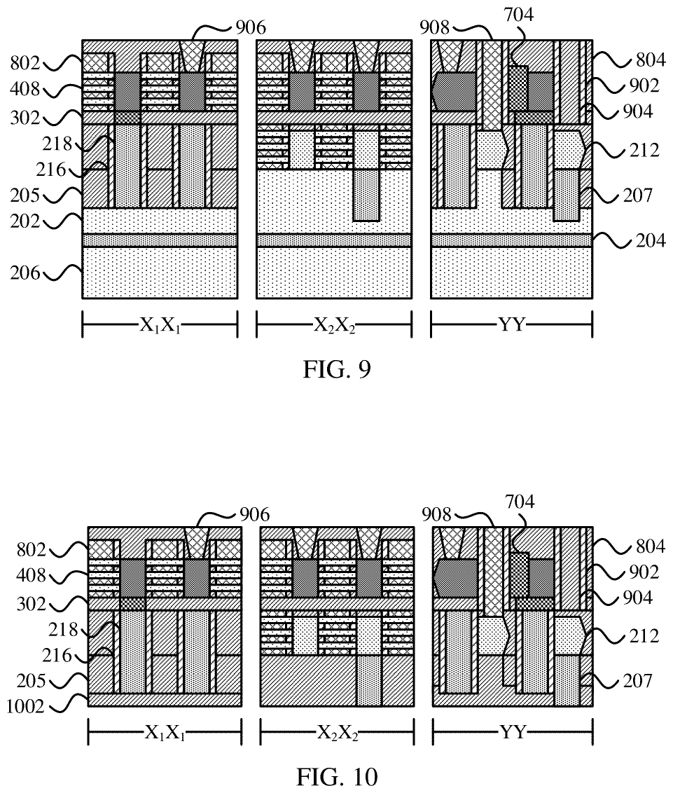

Referring now to FIG. 9, a set of cross-sectional views is shown of a step in the fabrication of shifted stacked FETs. A gate cut formed by etching through the top layer, forming openings through the top interlayer dielectric 804 and other structures to penetrate the bonding oxide 302. The gate cut may include a bi-layer dielectric fill, including a dielectric liner 902 and a dielectric fill 904, being formed from different dielectric materials. For example, the dielectric liner 902 may be formed from silicon nitride by a conformal deposition, and the dielectric fill 904 may be formed by any appropriate deposition of silicon dioxide. The dielectric liner 902 and dielectric fill 904 isolate from adjacent epitaxial growth.

In another region, a similar process may be used to form a frontside bottom contact 908. A via may be formed that penetrates through the top layer to expose a bottom S/D structure 212. The formation of the dielectric liner 902 of the gate cut can further form a liner in this via before a conductive material is deposited to form the frontside bottom contact 908. Frontside top contacts 906 can similarly be formed by etching vias into the top interlayer dielectric 804 to expose top S/D structures 602 and depositing conductive material into the vias.

At this stage, additional layers may be added to the front side of the device, such as back-end-of-line (BEOL) layers (not shown) and a carrier wafer (not shown). The BEOL layers may include conductive interconnects and vias to provide electrical connectivity to the frontside top contacts 906 and the frontside bottom contact 908. The carrier wafer may be bonded to the BEOL layers so that the device can be flipped upside-down to expose the back side for further processing.

Referring now to FIG. 10, a set of cross-sectional views is shown of a step in the fabrication of shifted stacked FETs. The carrier substrate 206, the etch stop layer 204, and the semiconductor substrate 202 are etched away, exposing the backside bottom contact placeholder 207 and the bottom layer placeholder 218. A backside interlayer dielectric 1002 is deposited by any appropriate deposition process, for example depositing a dielectric material such as silicon dioxide. Excess dielectric material may be removed by a CMP process that stops on the backside bottom contact placeholder 207.

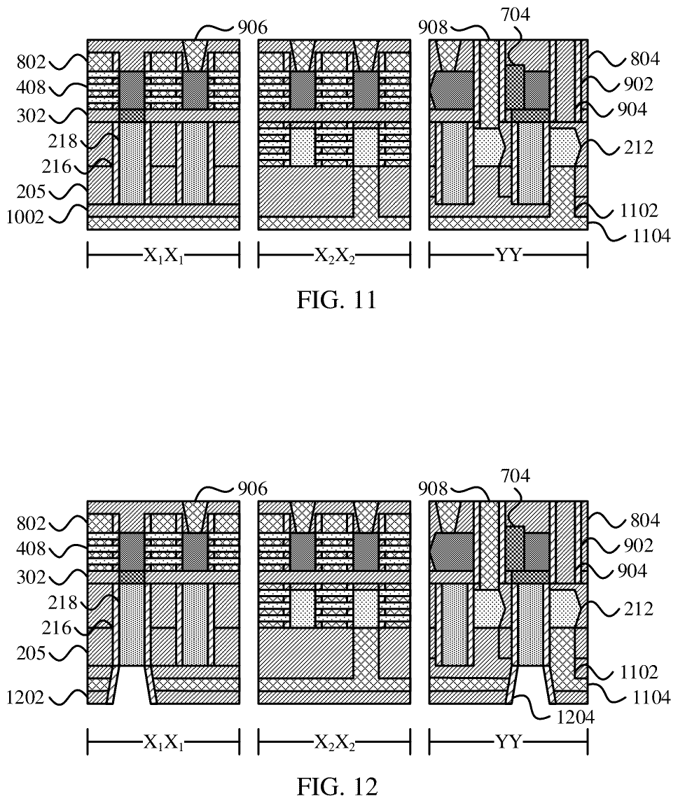

Referring now to FIG. 11, a set of cross-sectional views is shown of a step in the fabrication of shifted stacked FETs. The backside bottom contact placeholder 207 is selectively etched away, exposing the associated bottom S/D structure 212. The resulting hole through the backside interlayer dielectric 1002 is filled with conductive material, deposited by any appropriate deposition process or mixed growth processes, to form backside bottom contact 1102 and backside power plane 1104.

Referring now to FIG. 12, a set of cross-sectional views is shown of a step in the fabrication of shifted stacked FETs. Additional dielectric material is deposited on the backside power plane 1104 to form a thicker backside interlayer dielectric 1202. A via is formed through the backside interlayer dielectric 1202 and the backside power plane 1104 to expose the bottom layer placeholder 218. A dielectric liner 1204 is formed in the via, for example by conformal deposition of silicon nitride followed by a selective anisotropic etch that removes material from horizontal surfaces.

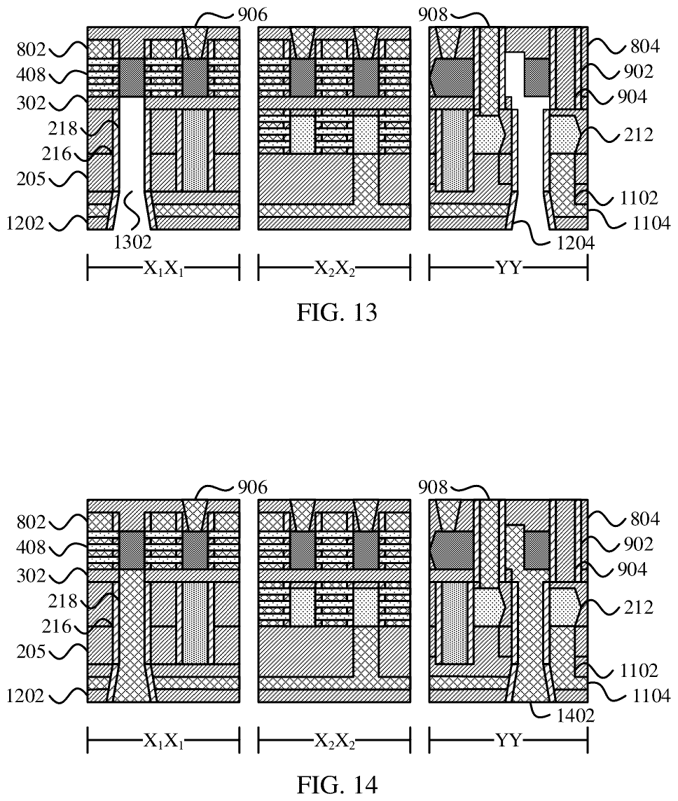

Referring now to FIG. 13, a set of cross-sectional views is shown of a step in the fabrication of shifted stacked FETs. The bottom layer placeholder 218 are selectively etched away, along with the interlayer placeholder 502 and the top layer placeholder 704. This leaves opening 1302, which exposes the underside and side surface of a top S/D structure 602.

Referring now to FIG. 14, a set of cross-sectional views is shown of a step in the fabrication of shifted stacked FETs. Conductive material is deposited using a conformal deposition process that fills the opening 1302, including along the exposed top S/D structure 602 to form a backside top contact 1402 that makes electrical contact with a bottom and side surface of the top S/D structure 602. Excess conductive material can be removed with a CMP process that stops on the backside interlayer dielectric 1202.

At this stage, additional layers may be added to the back side of the device, such as backside interconnect layers (not shown). The backside interconnect layers may include conductive interconnects and vias to provide electrical connectivity to the backside top contact 1402 and may include backside power distribution.

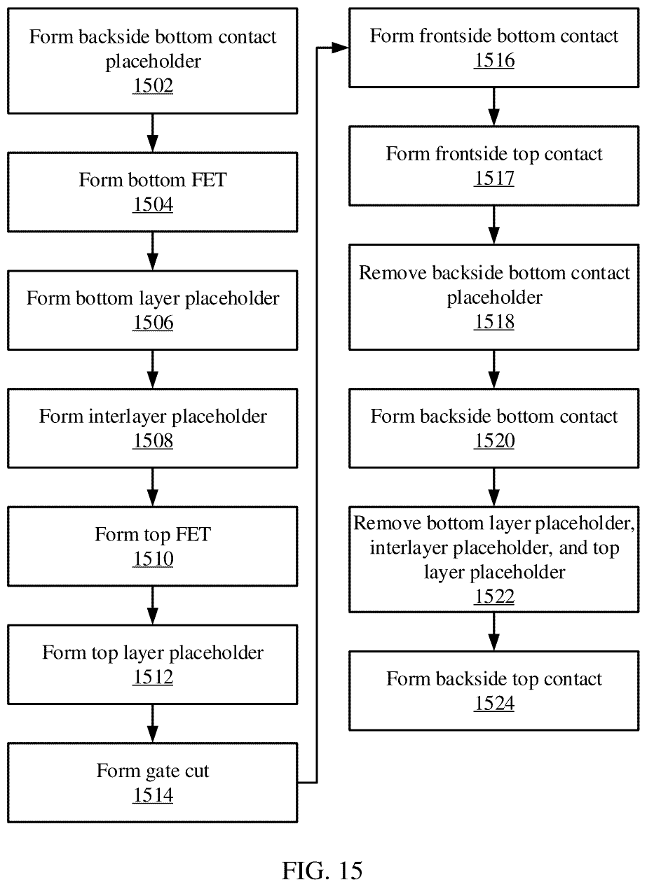

Referring now to FIG. 15, a method of forming a semiconductor device is shown. Block 1502 forms a backside bottom contact placeholder 207 in a semiconductor substrate 202. Block 1504 forms a bottom FET over the backside bottom contact placeholder 207 as described above, for example using alternating semiconductor nanosheets to form bottom channel layers 210 and epitaxially growing bottom S/D structures 212 from exposed sidewalls of the bottom channel layers 210.

Block 1506 forms bottom layer placeholder 218, for example by etching a via, forming dielectric contact spacers 216, and then depositing conductive material to fill the via. Block 1508 forms a layer of bonding oxide 302 with interlayer placeholder 502. Block 1510 forms a top FET, for example using alternating semiconductor layers to form upper channels 408 and epitaxially growing top S/D structures 602 from exposed side surfaces of the upper channels 408.

Block 1512 forms a top layer placeholder 704 by depositing a top interlayer dielectric 804, etching an opening in the top interlayer dielectric 804, and depositing a selectively etchable placeholder material in the opening. Block 1514 forms a gate cut by etching a via through top interlayer dielectric 804, conformally forming a dielectric liner 902 in the via, and then filling the via with dielectric fill 904. Block 1516 forms frontside bottom contact 908 by etching a via through the top interlayer dielectric 804, making a dielectric liner therein, and filling the via with conductive material that makes an electrical connection to a bottom S/D structure 212. Bock 1517 forms frontside top contacts 906 by etching a via through the top interlayer dielectric 804 and filling with conductive material to make an electrical connection to a top S/D structure 602.

Block 1518 removes the backside bottom contact placeholder 207 using a selective etch. Block 1520 then forms backside bottom contact 1102 by depositing conductive material in the space left behind by the removal of the backside bottom contact placeholder 207. Block 1522 removes the bottom layer placeholder 207, the interlayer placeholder 502, and the top layer placeholder 704 with one or more selective isotropic etches, exposing a bottom and side surface of the top S/D structure 602. Block 1524 then forms backside top contact 1402 by conformally depositing conductive material in the opening left behind by the removal of placeholder structures in block 1522.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of shifted stacked FETs with improved S/D contacts (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a bottom field effect transistor (FET) having a bottom source/drain (S/D) structure;
a top FET above the bottom FET, having a top S/D structure;
a backside top contact that is in electrical contact with a bottom surface and a side surface of the top S/D structure and that extends below the bottom FET; and
a dielectric liner, disposed along sidewalls of the backside top contact, that separates the backside top contact from the bottom S/D structure.

2. The semiconductor device of claim 1, wherein the top S/D structure is laterally shifted relative to the bottom S/D structure.

3. The semiconductor device of claim 1, further comprising a backside power plane below the bottom FET.

4. The semiconductor device of claim 3, wherein the backside top contact extends through the backside power plane, wherein the dielectric liner further separates the backside top contact from the backside power plane.

5. The semiconductor device of claim 3, further comprising a backside bottom contact that is in electrical contact with the backside power plane and the bottom S/D structure.

6. The semiconductor device of claim 5, wherein the dielectric liner is in direct contact with the backside bottom contact.

7. The semiconductor device of claim 1, further comprising a gate cut structure isolating the backside top contact from a neighboring top FET.

8. The semiconductor device of claim 7, wherein the gate cut structure includes a dielectric liner of a first dielectric material and a dielectric fill of a second dielectric material.

9. The semiconductor device of claim 8, wherein the first dielectric material is silicon nitride and the second dielectric material is silicon dioxide.

10. The semiconductor device of claim 1, wherein the side surface of the top S/D structure is a flat, vertical surface.

11. A semiconductor device, comprising:
a first bottom field effect transistor (FET) having a first bottom source/drain (S/D) structure;
a first top FET above the first bottom FET, having a first top S/D structure that is laterally shifted relative to the first bottom S/D structure;
a backside power plane below the first bottom FET;
a backside bottom contact that is in electrical contact with the backside power plane and the first bottom S/D structure;
a backside top contact that extends through the backside power plane from below the first bottom FET and that is in electrical contact with a bottom surface and side surface of the first top S/D structure; and
a dielectric liner, disposed along sidewalls of the backside top contact, that separates the backside top contact from the backside power plane.

12. The semiconductor device of claim 11, further comprising a second top FET adjacent to the first top FET, with a gate cut structure isolating the backside top contact from a second top S/D structure of the second top FET.

13. The semiconductor device of claim 12, wherein the gate cut structure includes a dielectric liner of a first dielectric material and a dielectric fill of a second dielectric material.

14. The semiconductor device of claim 12, further comprising a second bottom FET adjacent to the first bottom FET, with a second bottom S/D structure that is laterally shifted relative to the second top S/D structure.

15. The semiconductor device of claim 14, further comprising a frontside top contact that makes an electrical connection to the second top S/D structure from above the first top FET and a frontside bottom contact that makes an electrical connection to the second bottom S/D structure from above the first top FET.

16. A semiconductor device, comprising:
a first bottom field effect transistor (FET) having a first bottom source/drain (S/D) structure;
a first top FET above the first bottom FET, having a first top S/D structure;
a second top FET adjacent to the first top FET;
a second bottom FET adjacent to the first bottom FET;
a backside top contact that is in electrical contact with a bottom surface and side surface of the first top S/D structure and that extends below the first bottom FET;
a dielectric liner, disposed along sidewalls of the backside top contact, that separates the backside top contact from the first bottom S/D structure; and
a gate cut structure that isolates the backside top contact from the second top FET and that includes a dielectric liner of a first dielectric material and a dielectric fill of a second dielectric material.

17. The semiconductor device of claim 16, further comprising a backside power plane below the first bottom FET.

18. The semiconductor device of claim 17, wherein the backside top contact penetrates the backside power plane, with the dielectric liner insulating the backside top contact from the backside power plane.

19. The semiconductor device of claim 17, further comprising a backside bottom contact that is in electrical contact with the backside power plane and the first bottom S/D structure.

20. The semiconductor device of claim 19, wherein the dielectric liner is in direct contact with the backside bottom contact.
